(19) United States
(12) Patent Application Publication
(10) Pub. No.: US 2026/0324355 A1
(43) Pub. Date: Oct. 15, 2026

(54) ELECTROSTATIC CHUCK HEATER AND METHOD OF MANUFACTURING THE SAME

(71) Applicant: TEMNEST INC., Hwaseong-si (KR)

(72) Inventors: Hae Ran KIM, Hwaseong-si (KR); Young Jae JEON, Yongin-si (KR); Jae Hyun LEE, Yongin-si (KR)

(73) Assignee: TEMNEST INC., Hwaseong-si (KR)

(21) Appl. No.: 19/643,563

(22) Filed: Apr. 9, 2026

(30) Foreign Application Priority Data
Apr. 10, 2025 (KR) 10-2025-0046950

(51) Int. Cl. H10P 72/72; B22F 3/14; B22F 5/00; H02N 13/00; H10P 72/00

(52) U.S. Cl. CPC H10P 72/722; B22F 3/14; H10P 72/0432; B22F 2005/002; H02N 13/00

(57) ABSTRACT

The present disclosure relates to an electrostatic chuck heater and a method of manufacturing the same. A problem in that the yield of a wafer is reduced due to a partial destruction phenomenon attributable to thermal expansion of an electrostatic chuck heater is solved and the lifespan of a wafer is increased by making a coefficient of thermal expansion of a lower plate of an electrostatic chuck similar to a coefficient of thermal expansion of an upper plate of the electrostatic chuck heater.

### CROSS-REFERENCE TO RELATED APPLICATION(S)

This U.S. non-provisional patent application claims priority to and the benefits of Korean Patent Application No. 10-2025-0046950 under 35 U.S.C. § 119, filed in the Korean Patent Intellectual Property Office on Apr. 10, 2025, the entire contents of which are hereby incorporated by reference.

### BACKGROUND

### 1. Technical Field

The present disclosure relates to an electrostatic chuck heater for heating a wafer in a chamber used in a semiconductor manufacturing process, and more particularly, to an electrostatic chuck heater formed of a sintered body of mixed powder and a method for manufacturing the same.

### 2. Related Art

An integrated circuit manufacturing process for a semiconductor wafer is a representative multi-step process, and is performed from at least tens of steps to several hundreds of steps. A semiconductor manufacturing process is basically performed within a high-temperature and high-pressure chamber for each wafer. A finished product is gradually produced by repeating a fine processing process under various chambers and various environments. Representative process steps include steps, such as deposition, exposure, etching, and ion implantation. By repeating such processes under various conditions, active elements, such as a transistor or a diode, are generated within a silicon substrate and various types of conductive layers that connect the active elements or insulating layers are repeatedly formed on the silicon substrate. As described above, such a process in the wafer state is basically performed within a semiconductor manufacturing facility or a chamber within the facility.

In order to generate a desired chemical reaction on the wafer in the state in which various temperatures and pressure set for each process step in order to perform the pre-process have been applied, various types of gases are input to the chamber through a shower head. Sometimes, plasma is generated by using the various types of gases. The wafer within the chamber needs to be seated and fixed so that the wafer is not moved while the process is performed. A structure that is used for the seating and fixing of the wafer is a chuck. Such an ESC is basically used to horizontally fix and seat a semiconductor wafer and is also used to horizontally fix a glass substrate of an LCD having a large size.

When power is supplied to the ESC through an electrode embedded in the ESC after a semiconductor wafer is input to the chamber and seated in the ESC, static electricity is generated on a surface of the ESC, and chucking in which the wafer is firmly fixed to the ESC is performed. One step of the pre-process under a high temperature and high pressure is performed. After the process of one step is completed, when the power that is supplied to the ESC is blocked, dechucking in which the wafer is separated from the ESC is performed.

Accordingly, the wafer can be separated from the ESC. Meanwhile, an electrostatic chuck heater including a heater unit having a resistive heating element is commonly used.

In general, in a manufacturing process that is performed within the chamber, as a chemical material is input to the chamber, a chemical reaction under a high temperature and high pressure is generated. Sometimes, the manufacturing process may be performed in a plasma state. Such a process is repeated innumerably until a separate maintenance and repair period is reached. Therefore, the ESC and ESC heater also need to have high durability, high corrosion resistance, and a high insulating characteristic. It is essentially required that a coefficient of thermal expansion and thermal conductivity are also adjusted within proper standards.

A common electrostatic chuck (ESC) heater 100 illustrated in FIG. 1 includes an upper plate 120 configured to directly contact and support a wafer (10) while performing an electrostatic chuck function, a lower plate (130) bonded to the upper plate (120) and configured to perform a heater function, and an adhesive (150) for bonding the plates. The upper plate 120 is made of ceramic having a thin thickness of approximately 1 mm to 5 mm in order to facilitate the transfer of heat to the wafer 10. A material, such as epoxy, is used as the adhesive 150. A material containing a metal component is used a lot as the lower plate 130 for the transfer of heat to the ESC heater 100.

However, the upper plate 120 and the lower plate 130 have different coefficients of thermal expansion due to different materials. In a chamber environment in which a change in the temperature is severe, the upper plate 120 and the lower plate 130 are spaced apart from each other to the extent that the adhesive is torn, or a destruction problem in which the upper plate is broken additionally occurs. As a result, other problems are additionally caused in terms of maintenance, a repair, and the yield.

For example, the upper plate made of ceramic has a coefficient of thermal expansion (CTE) of approximately 0.4 to 13.5 [μm/° C.], whereas the lower plate made of aluminum has a CTE of 20 to 30 [μm/° C.]. Therefore, the greater the difference between a temperature when the upper plate and the lower plate are bonded and combined and a temperature in an environment for a process that is performed within the chamber, the bonding of the upper plate and the lower plate is more likely to be broken or the upper plate made of ceramic is more likely to be broken. The reason for this is that the upper plate made of ceramic is harder than the lower plate made of aluminum and is softer than the lower plate made of aluminum. If a difference between the temperatures is 100° C. even through simple calculation based on thermal expansion, a difference attributable to a change in the sizes of the upper plate and the lower plate may be greater than 1,000 μm. This becomes a great problem.

In particular, an etch process or a plasma process at a temperature lower than a room temperature becomes more important because the aspect ratio of a structure that is vertically formed in a semiconductor integrated circuit is recently several tens to hundreds. Accordingly, such a temperature adaptability problem in the ESC in which a temperature of the wafer is directly adjusted becomes more serious.

For reference, known coefficients of thermal expansion of magnesia (MgO), alumina (Al₂O₃), soda-lime glass, and silica (SiO₂) that belong to ceramic are about 13.5, 7.6, 9.0, and 0.4 [μm/° C.], respectively, and have some errors depending on a measurement environment and a degree of impurities contained.

A problem attributable to a difference in the CTE is the same even in a below zero environment in which a temperature gradually drops from a room temperature in a use environment. The CTE refers to a numerical value that is increased whenever a temperature rises every 1° C. When a temperature drops every 1° C., thermal contraction occurs, and the CTE becomes negative (−) value.

### SUMMARY

Various embodiments are directed to a construction which makes a coefficient of thermal expansion of a lower plate of an electrostatic chuck heater equivalent to or at least approximate to a coefficient of thermal expansion of an upper plate of the electrostatic chuck, and method of manufacturing the same.

Also, various embodiments are directed to enabling a user to reduce costs and the time for maintenance and repairs by further extending the lifespan of an electrostatic chuck.

Also, various embodiments are directed to preventing a problem in which the yield of a wafer is reduced due to a partial destruction phenomenon attributable to thermal expansion of an electrostatic chuck heater.

In an embodiment, there is provided an electrostatic chuck heater including an upper plate made of ceramic and having a wafer seated therein, a lower plate bonded to the upper plate, and an adhesive for bonding the upper plate and the lower plate together. The upper plate includes an electrostatic electrode embedded in a ceramic sintered body and operates as an electrostatic chuck. The lower plate includes a resistive heating element therein and operates as a heater. The lower plate may be sintered and molded at a high temperature under vacuum and pressurization by mixing first powder including at least one of aluminum, stainless steel (SUS), titanium, and magnesium and second powder including at least one of silicon-carbide (SiC), silicon nitride (Si₃N₄), silicon, diamond, carbon nanotubes, and graphene. A mixing ratio of the first powder and the second powder may be 4:6 to 6:4.

In an embodiment, there is provided an electrostatic chuck heater including a lower plate and an upper plate formed by coating on an upper portion of the lower plate. The upper plate includes a first ceramic layer coated on the upper portion of the lower plate, a metal electrode layer coated on the first ceramic layer, and a second ceramic layer coated on the metal electrode layer, and operates as an electrostatic chuck. The lower plate includes a resistive heating element therein and operates as a heater.

In an embodiment, there is provided a method of manufacturing an electrostatic chuck heater comprises: an upper plate manufacturing step of manufacturing an upper plate, on which a wafer is seated and which operates as an electrostatic chuck, using a ceramic sintered body; a lower plate manufacturing step of manufacturing a lower plate configured to operate as a heater; and a bonding step of bonding the upper plate and the lower plate, wherein the lower plate manufacturing step comprises: a first powder preparation step of preparing a first powder including at least one selected from aluminum, stainless steel (SUS), titanium, and magnesium; a second powder preparation step of preparing a second powder including at least one selected from silicon carbide (SiC), silicon nitride (Si₃N₄), silicon, diamond, carbon nanotubes, and graphene; a powder mixing step of mixing the first powder and the second powder; and a sintering and molding step of forming a lower plate molded body by high-temperature sintering of the mixed powder under vacuum and pressure. The mixing ratio of the first powder to the second powder in the powder mixing step is in a range of 4:6 to 6:4.

In an embodiment, there is provided a method of manufacturing an electrostatic chuck heater comprises; a lower plate manufacturing step of manufacturing a lower plate configured to operate as a heater; and an upper plate coating step of coating an upper plate, which operates as an electrostatic chuck, on an upper portion of the lower plate. The upper plate coating step comprises: a first ceramic layer coating step of coating a first ceramic layer on the upper portion of the lower plate; a metal electrode layer coating step of coating a metal electrode layer on the first ceramic layer; and a second ceramic layer coating step of coating a second ceramic layer on the metal electrode layer.

The present disclosure has an effect in that a user can reduce costs and the time for maintenance and repairs by further extending the lifespan of an ESC heater.

The present disclosure has effects in that it can prevent a problem in which the yield of a wafer is reduced by minimizing a partial destruction phenomenon attributable to thermal expansion of an ESC heater and can improve productivity in a semiconductor mass-production process.

### BRIEF DESCRIPTION OF THE DRAWINGS

FIG. 1 is a diagram schematically illustrating a common ESC heater according to a conventional technology.

FIG. 2 is a diagram schematically illustrating an ESC heater according to an embodiment of the present disclosure.

FIG. 3 is a diagram illustrating a process of forming a lower plate of the ESC heater in FIG. 2.

FIG. 4 is a schematic view illustrating an electrostatic chuck heater according to another embodiment of the present invention.

FIG. 5 is a diagram illustrating coefficients of thermal expansion according to composition ratios of a composition of the lower plate of the ESC heater according to an embodiment of the present disclosure.

FIG. 6 is a diagram illustrating a flow of a method of manufacturing an ESC heater according to an embodiment of the present disclosure.

FIG. 7 is a flowchart illustrating a method for manufacturing an electrostatic chuck heater according to another embodiment of the present invention.

### DETAILED DESCRIPTION

Hereinafter, embodiments of the present disclosure are described in detail with reference to the accompanying drawings so that a person having ordinary knowledge in the art to which the present disclosure pertains may easily practice the embodiments. In reference numerals presented in the drawings, the same reference number indicates the same member.

In describing the present disclosure, when it is determined that a detailed description of a related known technology may obscure the subject matter of the present disclosure, the detailed description is omitted.

Terms, such as a first and a second, may be used to describe various components, but the components are not restricted by the terms. The terms are used to only distinguish one component from another component.

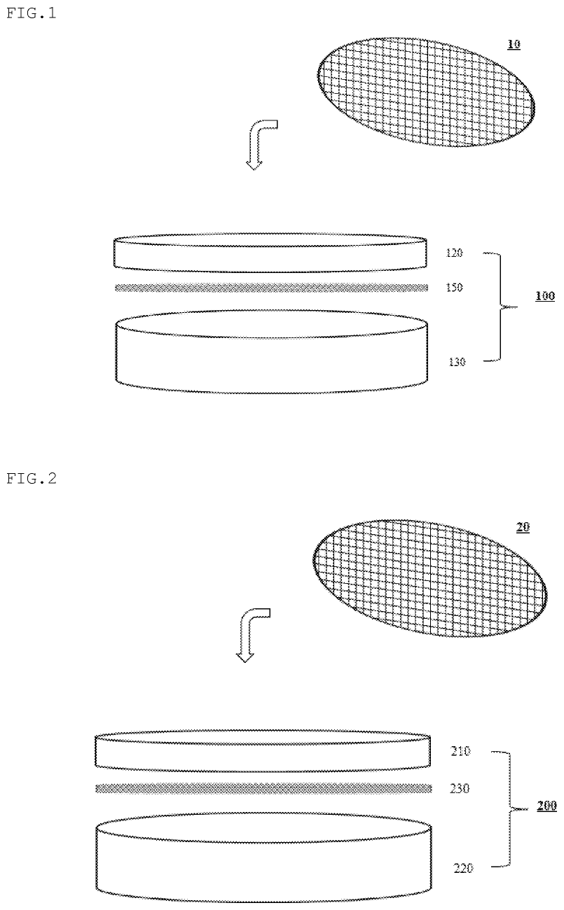

FIG. 2 is a diagram schematically illustrating an electrostatic chuck (ESC) heater according to an embodiment of the present disclosure. FIG. 3 is a diagram illustrating a process of forming a lower plate of the ESC heater in FIG. 2.

Referring to FIG. 2, an electrostatic chuck heater (200) according to the present invention includes an upper plate (210) configured to directly contact and support a wafer (20) while performing an electrostatic chuck function, a lower plate (220) bonded to the upper plate (210) and configured to perform a heating function, and an adhesive (230) for bonding the upper plate (210) and the lower plate (220).

The upper plate 210 configured to perform an electrostatic chuck function is made of ceramic having a thin thickness of approximately 1 mm to 5 mm in order to facilitate the transfer of heat to the wafer 20. A material, such as epoxy, is used as the adhesive 230. The lower plate (220) is formed of a material including a metal component for heat transfer of the electrostatic chuck heater (200), and includes at least one resistive heating element therein.

The ESC heater 200 according to an embodiment of the present disclosure can solve a problem in that the adhesive is torn or the upper plate is broken by making a coefficient of thermal expansion of the lower plate 220, which performs a heating function, identical with a coefficient of thermal expansion of the upper plate 210, which performs an electrostatic chuck function, or minimizing a difference between the coefficients of thermal expansion of the lower plate 220 and the upper plate 210.

In the ESC heater 200 according to an embodiment of the present disclosure, the lower plate 220 is sintered and molded at a high temperature under vacuum and pressurization by mixing first powder including at least one of aluminum, stainless steel, titanium, and magnesium and second powder including at least one of silicon-carbide (SiC), silicon nitride (Si₃N₄), silicon, diamond, carbon nanotubes, and graphene. In this case, it is preferred that the mixing ratio of the first powder and the second powder is 4:6 to 6:4.

In order to make a coefficient of thermal expansion of the lower plate 220 identical with a coefficient of thermal expansion of the upper plate 210 or minimize a difference between the coefficients of thermal expansion of the lower plate 220 and the upper plate 210, it is very important to adjust the ratio of the particle size of the first powder and the second powder in addition to the mixing ratio of the first powder and the second powder.

In the ESC heater 200 according to an embodiment of the present disclosure, it is preferred that the ratio of the particle size of the first powder and the second powder of the lower plate 220 is adjusted in the range of 1:0.05 to 1:0.4.

It is preferred that the lower plate 220 is sintered and molded at a temperature of 300° C. to 700° C. and pressure of 10 MPa to 300 MPa for 30 minutes to 2 hours.

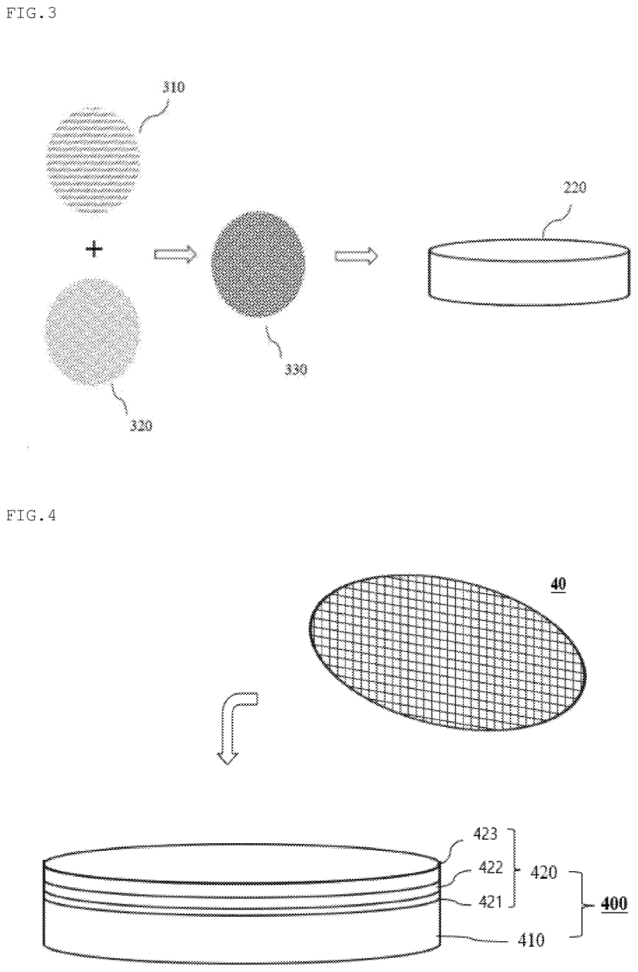

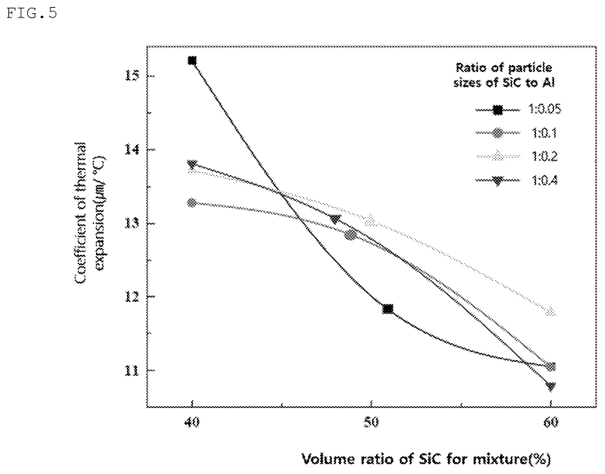

FIG. 4 is a schematic view illustrating an electrostatic chuck heater according to another embodiment of the present invention.

Referring to FIG. 4, an electrostatic chuck heater (400) according to another embodiment of the present invention includes a lower plate (410) configured to perform a heating function, and an upper plate (420) configured to directly contact and support a wafer (40) while performing an electrostatic chuck function.

Since the lower plate (410) configured to perform a heating function is the same as the lower plate (220) shown in FIG. 2, a detailed description thereof will be omitted.

The upper plate (420), which performs an electrostatic chuck function, is formed by being coated on an upper portion of the lower plate (410).

The upper plate (420) includes a first ceramic layer (421) coated on the upper portion of the lower plate (410), a metal electrode layer (422) coated on the first ceramic layer (421), and a second ceramic layer (423) coated on the metal electrode layer (422).

In this case, the first ceramic layer (421) and the second ceramic layer (423) may be formed of a material including at least one selected from alumina (Al₂O₃), aluminum nitride (AlN), and silicon nitride (SiN).

FIG. 5 is a diagram illustrating coefficients of thermal expansion according to composition ratios of a composition of the lower plate of the ESC heater according to an embodiment of the present disclosure.

In FIG. 5, an example in which Al6061, that is, an aluminum alloy, was used as the first powder and silicon-carbide (SiC) was used as the second powder has been described, but the first powder and the second powder are not limited to the example.

Referring to FIG. 5, it may be seen that a coefficient of thermal expansion of the composition is in the range of 10.79 (μm/m·° C.) to 15.21 (μm/m·° C.) if the ratio of silicon-carbide (SiC), that is, the second powder, to a mixture of the aluminum alloy (Al6061) and silicon-carbide (SiC) is in the range of 40 to 60 volumes and if the ratio of the particle size of silicon-carbide (SiC), that is, the second powder, to the aluminum alloy (Al6061), that is, the first powder, is in the range of 1:0.05 to 1:0.4.

The results of FIG. 5 are indicated in the form of a table as follows.

TABLE 1

Ratio of particle size of SiC to AI

| | | 1:0.05 | 1:0.1 | 1:0.2 | 1:0.4 |
|---|---|---|---|---|---|
| Volume ratio | 40 | 15.21 | 13.28 | 13.72 | 13.81 |
| (%) of SiC | 50 | 11.45 | 13.01 | 13.17 | 13.03 |
| | 60 | 11.05 | 11.05 | 11.79 | 10.79 |

The lower plate having a coefficient of thermal expansion within a preferred range can be obtained if the ratio of the particle size of silicon-carbide (SiC), that is, the second powder, to the aluminum alloy (Al6061), that is, the first powder, is adjusted in the range of 1:0.05 to 1:0.4 and the ratio of silicon-carbide (SiC), that is, the second powder, is adjusted in the range of 40 to 60 volume %.

In this case, if the ratio of the particle size of silicon-carbide (SiC), that is, the second powder, to the aluminum alloy (Al6061), that is, the first powder, is less than 1:0.05, there is a problem in that a heat transfer coefficient is suddenly reduced because the density and dispersibility of the powers is deteriorated and the density is reduced after sintering. Furthermore, if the ratio of the particle size of silicon-carbide (SiC), that is, the second powder, to the aluminum alloy (Al6061), that is, the first powder, is greater than 1:0.4, there is a problem in that the coefficient of thermal expansion is reduced because a bonding force between the particles is reduced.

TABLE 2

| | Coefficient of thermal |
|---|---|
| Mixture | expansion (10⁻⁶/K) |
| Al-1% SiC (ratio of particle sizes | 22.29 |
| 1:0.2) | |
| Al-5% SiC (ratio of particle sizes | 23.46 |
| 1:0.2) | |
| Al-10% SiC (ratio of particle sizes | 22.56 |
| 1:0.2) | |
| Al-20% SiC (ratio of particle sizes | 21.12 |
| 1:0.2) | |
| Al-30% SiC (ratio of particle sizes | 19.98 |
| 1:0.2) | |
| Al-40% SiC (ratio of particle sizes | 13.72 |
| 1:0.2) | |
| Al-50% SiC (ratio of particle sizes | 13.17 |
| 1:0.2) | |
| Al-60% SiC (ratio of particle sizes | 11.79 |
| 1:0.2) | |
| Al-70% SiC (ratio of particle sizes | 10.12 |
| 1:0.2) | |
| Al-80% SiC (ratio of particle sizes | 10.01 |
| 1:0.2) | |

Table 2 illustrates the results of experiments on a characteristic change according to the ratio of silicon-carbide (SiC) for the mixture of the aluminum alloy (Al6061), that is, the first powder, and silicon-carbide (SiC), that is, the second powder.

From Table 2, it may be seen that when the ratio of silicon-carbide (SiC) for the mixture of the aluminum alloy (Al6061) and silicon-carbide (SiC) is 40% or less, a desired coefficient of thermal expansion cannot be obtained and when the ratio of silicon-carbide (SiC) for the mixture of the aluminum alloy (Al6061) and silicon-carbide (SiC) is more than is suddenly 40%, the coefficient of thermal expansion improved.

When the ratio of silicon-carbide (SiC) for the mixture of the aluminum alloy (Al6061) and silicon-carbide (SiC) is more than 60%, a characteristic distribution of the powders is deteriorated because the dispersibility of the powders, that is, a process of the powders being uniformly mixed, is reduced.

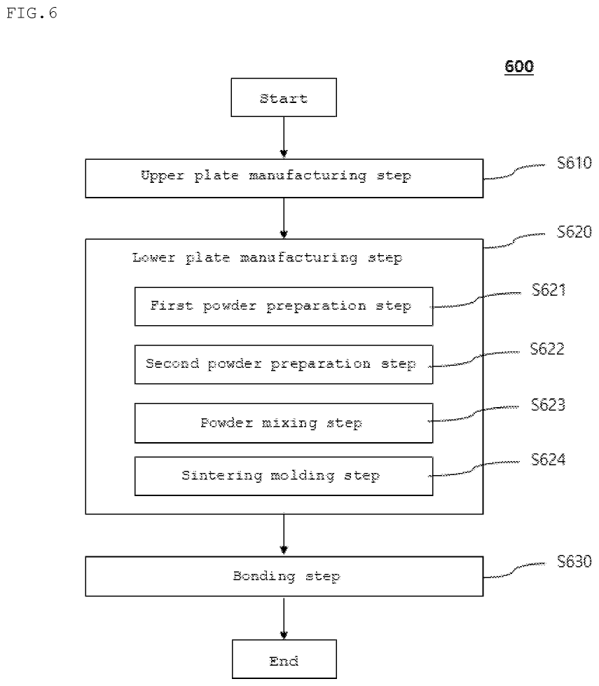

FIG. 6 is a diagram illustrating a flow of a method of manufacturing an ESC heater according to an embodiment of the present disclosure.

Referring to FIG. 6, the method of manufacturing an ESC heater according to an embodiment of the present 600 disclosure includes an upper plate manufacturing step (S610), a lower plate manufacturing step (S620), and a bonding step (S630).

In the upper plate manufacturing step (S610), an upper plate, on which a wafer is seated and which operates as an electrostatic chuck, is manufactured using a ceramic sintered body. In this case, an electrostatic electrode is provided within the upper plate.

In the lower plate manufacturing step (S620), a lower plate configured to operate as a heater is manufactured.

In the bonding step (S630), the upper plate and the lower plate are bonded to each other using an adhesive.

Meanwhile, the lower plate manufacturing step (S620) includes a first powder preparation step S621, a second powder preparation step S622, a powder mixing step S623, and a sintering molding step S624.

In the first powder preparation step S621, first powder 310, that is, molding body powder including at least one of aluminum, stainless steel, titanium, and magnesium, is prepared. When the ease of molding processing is considered, it is preferred that the prepared first powder includes aluminum as a major component of the material of the first powder. For reference, pure aluminum has a coefficient of thermal expansion of 23.8 [μm/° C.], alumina (Al₂O₃) has a coefficient of thermal expansion of 6.7 to 7.7 [μm/° C.], and aluminum-nitride (AlN) has a coefficient of thermal expansion of 4.5 to 5.0 [μm/° C.]. Hereinafter, the unit of a coefficient of thermal expansion is [μm/° C.].

In the second powder preparation step S622, second powder 320, that is, additive powder including at least one of silicon-carbide (SiC), silicon nitride (Si₃N₄), silicon, diamond, carbon nanotubes, and graphene, is prepared.

In the second powder 320, that is, additive powder, silicon-carbide (SiC) has a coefficient of thermal expansion of 4.5 to 6.6, silicon nitride (Si₃N₄) has a coefficient of thermal expansion of 2.6, stainless steel (SUS) has a coefficient of thermal expansion of 10 to 18 depending on standards thereof, diamond has a coefficient of thermal expansion of about 1.1, and carbon nanotubes have a coefficient of thermal expansion of 4 to 6 depending on a direction thereof and the content of fine carbon.

In the powder mixing step S623, the first powder 310, that is, the molding body powder, and the second powder 320, that is, the additive powder, are mixed. As an embodiment, Al6061, that is, an aluminum alloy, may be used as the first powder 310, and silicon-carbide (SiC) may be used as the second powder 320. In this case, it is preferred that the ratio of the particle size of the first powder and the second powder that are mixed is 1:0.05 to 1:0.4.

In this case, the volume of the second powder 320, that is, additive powder, may be properly adjusted, if necessary. For example, if silicon-carbide (SiC) is used as the second powder 320, the volume of silicon-carbide (SiC) may be increased or decreased within 40% to 60% of the entire mixed powder 330. If Al6061, that is, an aluminum alloy, is used as the first powder 310, a coefficient of thermal expansion of the mixed powder is gradually reduced from a coefficient of thermal expansion of aluminum depending on a mixed ratio thereof. Since it is expected that the second powder that is used as an additive is mixed with the first powder, it is preferred that a material is that advantageous in being pressurized and molded at a high temperature and that more facilitates the adjustment and prediction of a coefficient of thermal expansion of the material is selected as the second powder.

In the sintering molding step S624, the lower plate 220 is completed by molding the mixed powder as a sintering material by pressurizing the mixed powder. In this case, conditions for such sintering molding, that is, pressure, a temperature, and the time, are variable depending on a state of a desired finished sintering material. Preferably, it is better to perform the sintering molding at pressure of 10 MPa to 300 MPa and a temperature of 300° C. to 700° C. for 30 minutes to 2 hours. The sintering molding step S400 may be performed by using a cold press or a high pressure injection method.

In order to adjust a temperature of the lower plate, an resistive heating element needs to be buried in the lower plate. In this case, after a mold of the lower plate is divided by half and the two molds are separately manufactured, the resistive heating element needs to be buried between the two molds.

In an embodiment of the present disclosure, the sintering molding step S624 may be replaced with another method other than the aforementioned powder metallurgy method of pressurizing and molding the mixed powder. For example, the first powder may be first sintered, and a pouring method of first melting the first powder so that bubbles are properly formed in the first powder may be used. Thereafter, a method of melting the first powder through pressurization and filling the molten results with bubbles may be used. Alternatively, a method of first melting another first powder and then adding the second powder may be used.

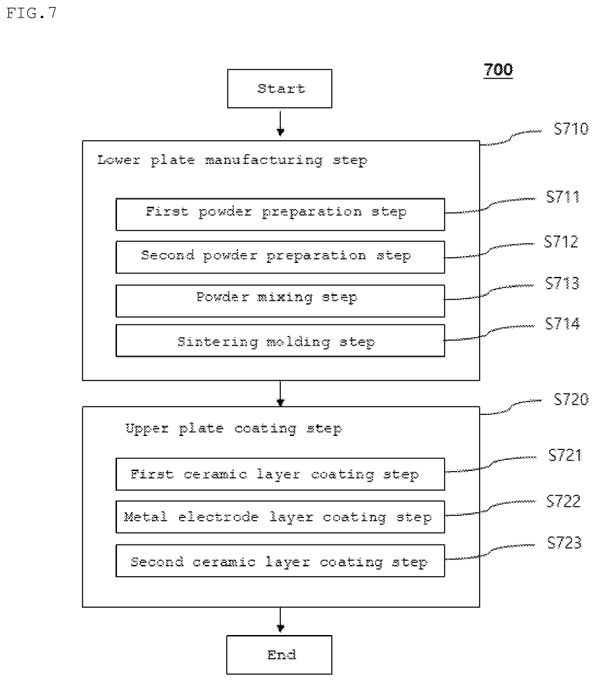

FIG. 7 is a diagram illustrating a flow of a method of manufacturing an ESC heater according to an another embodiment of the present disclosure.

Referring to FIG. 7, the method of manufacturing an ESC heater according to an embodiment of the present 700 disclosure includes a lower plate manufacturing step (S710), and a upper plate coating step (S720).

In the lower plate manufacturing step (S710), a lower plate configured to operate as a heater is manufactured.

Meanwhile, the lower plate manufacturing step (S710) includes a first powder preparation step S711, a second powder preparation step S712, a powder mixing step S713, and a sintering molding step S714.

In the first powder preparation step S711, first powder 310, that is, molding body powder including at least one of aluminum, stainless steel, titanium, and magnesium, is prepared. When the ease of molding processing is considered, it is preferred that the prepared first powder includes aluminum as a major component of the material of the first powder. For reference, pure aluminum has a coefficient of thermal expansion of 23.8 [μm/° C.], alumina (Al₂O₃) has a coefficient of thermal expansion of 6.7 to 7.7 [μm/° C.], and aluminum-nitride (AlN) has a coefficient of thermal expansion of 4.5 to 5.0 [μm/° C.]. Hereinafter, the unit of a coefficient of thermal expansion is [μm/° C.].

In the second powder preparation step S712, second powder 320, that is, additive powder including at least one of silicon-carbide (SiC), silicon nitride (Si₃N₄), silicon, diamond, carbon nanotubes, and graphene, is prepared.

In the second powder 320, that is, additive powder, silicon-carbide (SiC) has a coefficient of thermal expansion of 4.5 to 6.6, silicon nitride (Si₃N₄) has a coefficient of thermal expansion of 2.6, stainless steel (SUS) has a coefficient of thermal expansion of 10 to 18 depending on standards thereof, diamond has a coefficient of thermal expansion of about 1.1, and carbon nanotubes have a coefficient of thermal expansion of 4 to 6 depending on a direction thereof and the content of fine carbon.

In the powder mixing step S713, the first powder 310, that is, the molding body powder, and the second powder 320, that is, the additive powder, are mixed. As an embodiment, Al6061, that is, an aluminum alloy, may be used as the first powder 310, and silicon-carbide (SiC) may be used as the second powder 320. In this case, it is preferred that the ratio of the particle size of the first powder and the second powder that are mixed is 1:0.05 to 1:0.4.

In this case, the volume of the second powder 320, that is, additive powder, may be properly adjusted, if necessary. For example, if silicon-carbide (SiC) is used as the second powder 320, the volume of silicon-carbide (SiC) may be increased or decreased within 40% to 60% of the entire mixed powder 330. If Al6061, that is, an aluminum alloy, is used as the first powder 310, a coefficient of thermal expansion of the mixed powder is gradually reduced from a coefficient of thermal expansion of aluminum depending on a mixed ratio thereof. Since it is expected that the second powder that is used as an additive is mixed with the first powder, it is preferred that a material that is advantageous in being pressurized and molded at a high temperature and that more facilitates the adjustment and prediction of a coefficient of thermal expansion of the material is selected as the second powder.

In the sintering molding step S714, the lower plate 220 is completed by molding the mixed powder as a sintering material by pressurizing the mixed powder. In this case, conditions for such sintering molding, that is, pressure, a temperature, and the time, are variable depending on a state of a desired finished sintering material. Preferably, it is better to perform the sintering molding at pressure of 10 MPa to 300 MPa and a temperature of 300° C. to 700° C. for 30 minutes to 2 hours. The sintering molding step S400 may be performed by using a cold press or a high pressure injection method.

In order to adjust a temperature of the lower plate, an resistive heating element needs to be buried in the lower plate. In this case, after a mold of the lower plate is divided by half and the two molds are separately manufactured, the resistive heating element needs to be buried between the two molds.

In an embodiment of the present disclosure, the sintering molding step S714 may be replaced with another method other than the aforementioned powder metallurgy method of pressurizing and molding the mixed powder. For example, the first powder may be first sintered, and a pouring method of first melting the first powder so that bubbles are properly formed in the first powder may be used. Thereafter, a method of melting the first powder through pressurization and filling the molten results with bubbles may be used. Alternatively, a method of first melting another first powder and then adding the second powder may be used.

In the upper plate coating step (S720), an upper plate, on which a wafer is seated and which operates as an electrostatic chuck, is coated on an upper portion of the lower plate using a ceramic sintered body.

The upper plate coating step (S720) includes a first ceramic layer coating step (S721) of coating a first ceramic layer on the upper portion of the lower plate, a metal electrode layer coating step (S722) of coating a metal electrode layer on the first ceramic layer, and a second ceramic layer coating step (S723) of coating a second ceramic layer on the metal electrode layer.

In this case, the first ceramic layer and the second ceramic layer are preferably formed of a material including at least one selected from alumina (Al₂O₃), aluminum nitride (AlN), and silicon nitride (SiN).

What is claimed is:

1. An electrostatic chuck heater comprising an upper plate made of ceramic and having a wafer seated therein, a lower plate bonded to the upper plate, and an adhesive for bonding the upper plate and the lower plate together,
wherein the upper plate includes an electrostatic electrode embedded in a ceramic sintered body and operates as an electrostatic chuck,
wherein the lower plate includes a resistive heating element therein and operates as a heater,
wherein the lower plate is sintered and molded at a high temperature under vacuum and pressurization by mixing first powder comprising at least one of aluminum, stainless steel, titanium, and magnesium and second powder comprising at least one of silicon-carbide (SiC), silicon nitride (Si₃N₄), silicon, diamond, carbon nanotubes, and graphene, and
a mixing ratio of the first powder and the second powder is 4:6 to 6:4.

2. The electrostatic chuck heater of claim 1, wherein a ratio of a particle size of the first powder and the second powder is 1:0.05 to 1:0.4.

3. The electrostatic chuck heater of claim 1, wherein the lower plate is sintered and molded at a temperature of 300° C. to 700° C.

4. The electrostatic chuck heater of claim 1, wherein the lower plate is sintered and molded at pressure of 10 MPa to 300 MPa.

5. The electrostatic chuck heater of claim 1, wherein the lower plate is sintered and molded for 30 minutes to 2 hours.

6. An electrostatic chuck heater comprising a lower plate and an upper plate formed by coating on an upper portion of the lower plate,
wherein the upper plate includes a first ceramic layer coated on the upper portion of the lower plate, a metal electrode layer coated on the first ceramic layer, and a second ceramic layer coated on the metal electrode layer, and operates as an electrostatic chuck,
and wherein the lower plate includes a resistive heating element therein and operates as a heater.

7. The electrostatic chuck heater of claim 6,
wherein the lower plate is sintered and molded at a high temperature under vacuum and pressurization by mixing first powder comprising at least one of aluminum, stainless steel, titanium, and magnesium and second powder comprising at least one of silicon-carbide (SiC), silicon nitride (Si₃N₄), silicon, diamond, carbon nanotubes, and graphene, and
a mixing ratio of the first powder and the second powder is 4:6 to 6:4.

8. The electrostatic chuck heater of claim 7, wherein the first ceramic layer and the second ceramic layer include at least one selected from alumina (Al₂O₃), aluminum nitride (AlN), and silicon nitride (SiN).

9. The electrostatic chuck heater of claim 8, wherein a ratio of a particle size of the first powder and the second powder is 1:0.05 to 1:0.4.

10. The electrostatic chuck heater of claim 8, wherein the lower plate is sintered and molded at a temperature of 300° C. to 700° C.

11. The electrostatic chuck heater of claim 8, wherein the lower plate is sintered and molded at pressure of 10 MPa to 300 MPa.

12. The electrostatic chuck heater of claim 8, wherein the lower plate is sintered and molded for 30 minutes to 2 hours.

13. A method of manufacturing an electrostatic chuck heater comprising:
an upper plate manufacturing step of manufacturing an upper plate, on which a wafer is seated and which operates as an electrostatic chuck, using a ceramic sintered body;
a lower plate manufacturing step of manufacturing a lower plate configured to operate as a heater; and
a bonding step of bonding the upper plate and the lower plate,
wherein the lower plate manufacturing step comprises:
a first powder preparation step of preparing a first powder including at least one selected from aluminum, stainless steel (SUS), titanium, and magnesium;
a second powder preparation step of preparing a second powder including at least one selected from silicon carbide (SiC), silicon nitride (Si₃N₄), silicon, diamond, carbon nanotubes, and graphene;
a powder mixing step of mixing the first powder and the second powder; and
a sintering and molding step of forming a lower plate molded body by high-temperature sintering of the mixed powder under vacuum and pressure,
wherein a mixing ratio of the first powder to the second powder in the powder mixing step is in a range of 4:6 to 6:4.

14. The method of manufacturing an electrostatic chuck heater of claim 13, wherein in the powder mixing step, a ratio of a particle size of the first powder and the second powder is 1:0.05 to 1:0.4.

15. The method of manufacturing an electrostatic chuck heater of claim 13, wherein in the sintering and molding step is performed at a temperature in a range of 300° C. to 700° C.

16. The method of manufacturing an electrostatic chuck heater according to claim 13, wherein the sintering and molding step is performed at a pressure in a range of 10 MPa to 300 MPa.

17. The method for manufacturing an electrostatic chuck heater according to claim 13, wherein the sintering and molding step is performed for a duration of 30 minutes to 2 hours.

18. A method of manufacturing an electrostatic chuck heater comprising;
a lower plate manufacturing step of manufacturing a lower plate configured to operate as a heater; and
an upper plate coating step of coating an upper plate, which operates as an electrostatic chuck, on an upper portion of the lower plate,
wherein the upper plate coating step comprises:
a first ceramic layer coating step of coating a first ceramic layer on the upper portion of the lower plate;
a metal electrode layer coating step of coating a metal electrode layer on the first ceramic layer; and
a second ceramic layer coating step of coating a second ceramic layer on the metal electrode layer.

19. The method for manufacturing an electrostatic chuck heater according to claim 18,
wherein the lower plate manufacturing step comprises:
a first powder preparation step of preparing a first powder including at least one selected from aluminum, stainless steel (SUS), titanium, and magnesium;
a second powder preparation step of preparing a second powder including at least one selected from silicon carbide (SiC), silicon nitride (Si₃N₄), silicon, diamond, carbon nanotubes, and graphene;
a powder mixing step of mixing the first powder and the second powder; and
a sintering and molding step of forming a lower plate molded body by high-temperature sintering of the mixed powder under vacuum and pressure,
wherein a mixing ratio of the first powder to the second powder in the powder mixing step is in a range of 4:6 to 6:4.

20. The method for manufacturing an electrostatic chuck heater according to claim 19,
wherein the first ceramic layer and the second ceramic layer include at least one selected from alumina (Al₂O₃), aluminum nitride (AlN), and silicon nitride (SiN).

21. The method for manufacturing an electrostatic chuck heater according to claim 20,
wherein in the powder mixing step, a particle size ratio of the first powder to the second powder to be mixed is in a range of 1:0.05 to 1:0.4.

22. The method for manufacturing an electrostatic chuck heater according to claim 20,
wherein the sintering and molding step is performed at a temperature in a range of 300° C. to 700° C.

23. The method for manufacturing an electrostatic chuck heater according to claim 20,
wherein the sintering and molding step is performed at a pressure in a range of 10 MPa to 300 MPa.

24. The method for manufacturing an electrostatic chuck heater according to claim 20,
wherein the sintering and molding step is performed for a duration of 30 minutes to 2 hours.
